(19) United States
(12) Patent Application Publication
(10) Pub. No.: US 2008/0193721 A1
(43) Pub. Date: Aug. 14, 2008

(54) Methods for Structuring Substrate Surfaces

(76) Inventors: Michael Ukelis, Riedstadt (DE); Monika Kursawe, Seeheim-Jugenheim (DE)

Correspondence Address: MILLEN, WHITE, ZELANO & BRANIGAN, P.C., 2200 CLARENDON BLVD., SUITE 1400, ARLINGTON, VA, 22201, US

(21) Appl. No.: 12/065,171

(22) PCT Filed: Aug. 4, 2006
(86) PCT No.: PCT/EP2006/007708

§ 371 Date: Feb. 28, 2008

(30) Foreign Application Priority Data
Aug. 31, 2005 (DE) 10 2005 041 242.4

(51) Int. Cl. B05D 3/10; C23C 16/00; B32B 3/00

(52) U.S. Cl. 428/173; 427/299; 427/307; 427/250

(57) ABSTRACT

The present invention relates to processes for the structuring of surfaces of substrates in which a substrate is structured in a first step and, in a second step, coated by the sol-gel process for partial smoothing of the structuring, giving, in particular, a surface which scatters in a diffuse manner. The present invention likewise relates to substrates structured in this way and to the use thereof in optical applications

The present invention relates to processes for the structuring of surfaces of substrates in which a substrate is structured in a first step and, in a second step, coated by the sol-gel process for partial smoothing of the structuring, giving, in particular, a surface which scatters in a diffuse manner. The present invention likewise relates to substrates structured in this way and to the use thereof in optical applications.

Structured surfaces play a role in a number of applications and processes. Surface-structured substrates are also achieving increasing importance in optical applications, for example as diffusers or as reflectors. Optical diffusers are scattering surfaces at which incident light is scattered in a diffuse manner. Common examples of the use of optical diffusers are, for example, matt screens in photography and projection technology, onto which an image is projected. The light hitting the matt screen for image production is scattered thereby, i.e. deflected in various directions. This scattering results in the image projected onto the matt screen being visible from various directions. There is therefore a need for processes by means of which surfaces which scatter in a diffuse manner can be provided.

The object was therefore to provide processes for the structuring of a substrate surface which are simple to carry out and which facilitate the provision of structured surfaces for a wide range of applications.

Processes of the present invention satisfy the complex requirement profile in a surprising manner. The present invention accordingly relates to processes for the structuring of surfaces of substrates in which a substrate is structured in a first step and, in a second step, coated by the sol-gel process for partial smoothing of the structuring, giving, in particular, a surface which scatters in a diffuse manner.

For the purposes of the present invention, a structured surface is a surface which has a regular or irregular structure, in particular in the form of grooves, indentations or bumps of any type. The indentations and bumps can adopt any desired shape here and are in the nanometre to millimetre size range.

The process according to the invention has the advantage that it is simple to carry out and offers the possibility of producing structuring which scatters in a diffuse manner. The user is thus provided with the possibility of producing the structured surface necessary for his needs, where both process steps can be handled well technically, are simple to carry out and can be controlled well. Suitable applications are all optical systems in which scattering of the light is required.

In a specific embodiment, the process according to the invention may be suitable for the production of diffusers for liquid-crystal displays. In general, backlighting, which ensures adequate contrast, is employed for LCDs. In particular in the case of battery-supported LCDs, for example in notebooks, the associated energy consumption is evident in a negative way since the running time of the battery is additionally limited. For this reason, there is interest in the development of LCDs which do not need backlighting. This requires the use of reflectors, which should satisfy at least the following requirements:
incident light should be distributed uniformly over the entire area of the display in the viewing-angle range of the viewer
outside the viewing-angle range, as little reflection as possible should occur
the structuring should prevent interference phenomena.

With the process in accordance with the present invention, the provision of surfaces structured in this way is conceivable.

Suitable substrates in the present invention are glass substrates, ceramic substrates, metal substrates or plastic substrates, preferably glass, metal or ceramic substrates and very particularly preferably glass substrates or metal substrates. Glass substrates or metal substrates having structured surfaces are particularly suitable for optical applications, in particular for LCDs.

Suitable materials for glass substrates are all known glasses, for example float glass, cast glass of all glass compositions known to the person skilled in the art, A, C, D, E, ECR, R or S glasses.

Suitable metal substrates are, for example, polished or bright-drawn metal sheets having an average roughness value of <1 μm. Suitable plastic substrates consist, for example, of PMMA or polycarbonate. Suitable ceramic substrates are all ceramics known to the person skilled in the art, in particular transparent ceramics, which can be structured using one of the methods mentioned below.

In the two-step process of the present invention, structuring of the surface of the substrate is carried out in a first step. The structuring here can be carried out by the action of particle jets, laser beams, etching methods or embossing methods. Ideally, the structuring process is matched to the respective substrate in order to achieve optimum structuring. Thus, embossing methods are principally suitable in the case of substrates made of plastic or metals, where plastics are preferably structured with the aid of embossing methods. Etching methods are particularly suitable for glass or ceramic substrates, it being possible to employ all variants of etching methods known to the person skilled in the art, for example RIE (reactive ion etching).

Structuring is preferably carried out using particle jets, where the particle jets can be sand jets or electron beams. For the purposes of the present invention, sand jets are taken to mean all particle jets whose particles cannot be assigned to the atomic or subatomic size range (for example electrons). The size of the particles here can be in a range from 1 μm to 4 mm, depending on the desired structuring and the particle material employed. The particles preferably have a size of 5 μm to 1 mm and in particular of 20 μm to 200 μm.

Suitable jet materials are all customary materials, for example sand, glass, corundum, plastics, ceramics, nut shells, corn cob granules, steel of any quality and composition, metals, such as, for example, aluminium, and/or mixtures thereof. Preference is given to glass or corundum particles, in particular having a particle size of 5 to 100 μm and very particularly preferably having a particle size of 50 to 80 μm.

The jet pressure and the angle of incidence and the direction of the jet medium likewise affect the structure of the surface. Jet pressures of up to 10 bar, preferably up to 6 bar, are usually employed, with the angle of incidence usually being between 5 and 90°, preferably between 30 and 80°. The respective matching of the said parameters to the particle materials in order to adjust the desired type and depth of the structuring is part of the general ability of a person skilled in the art. The actual blasting operation is carried out correspondingly by a suitable machine in order to achieve the requisite reproducibility of the structure.

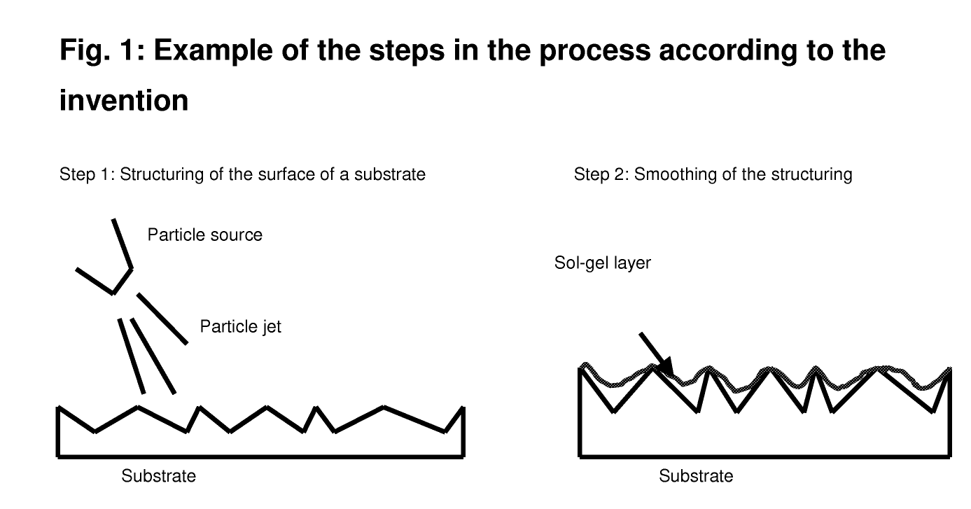

The structures obtained in this way generally still have edges which can adversely affect the properties in the later applications. For this reason, smoothing of the structuring is carried out in a second step of the processes according to the invention by coating by the sol-gel process. This smoothing partially re-fills indentations produced during the structuring and smooths corresponding edges by additional coating (see FIG. 1). In addition, refractive index adaptation in order to control the optical effects can be achieved by suitable mixing of corresponding sols, for example of TiO₂ and SiO₂ sols, by the sol-gel process. The second step carried out in the processes according to the invention thus serves not only for smoothing of the structuring produced in the first step, but can also serve for adaptation of the optical properties of the structured surface thus obtained.

Suitable sols for the sol-gel process are all sols known to the person skilled in the art, for example sols of compounds of the elements titanium, zirconium, silicon, aluminium and/or mixtures thereof. Preference is given to the use of silicon sols. Sols or precursors of this type are known and commercially available. The silicon sols are usually those in which the SiO₂ particles have been obtained by hydrolytic polycondensation of tetraalkoxysilane, in particular tetraethoxysilane (TEOS), in an aqueous/-alcoholic/ammoniacal medium. It is of course also possible to employ aqueous and/or solvent-containing sols prepared in a different manner as coating solution.

In addition, the coating solution may additionally contain surfactants. Furthermore, the coating solutions that can be employed for the sol-gel process may comprise further components, such as, for example, flow-control agents or complexing agents.

The respective solids content in the coating solution is usually in the range from 0.1 to 20% by weight, preferably from 2 to 10% by weight.

Coating solutions of the above-mentioned types are described, for example, in DE 198 28 231, U.S. Pat. No. 4,775,520, U.S. Pat. No. 5,378,400, DE 196 42 419, EP 1 199 288 or WO 03/027015, the disclosure contents of which are hereby incorporated into the present invention by way of reference. The coating by the sol-gel process is carried out in accordance with the general principles known to the person skilled in the art, for example by dip coating, spray methods or by means of a flow curtain. In the case of dip coating, the structured substrate is dipped into the coating solution, in the case of the spray methods, coating of the substrate with the coating medium is carried out by means of one- or multicomponent nozzles. On use of a flow curtain, the coating is carried out by means of a free-flowing curtain of the coating medium, under which the substrate to be coated is moved. The coating by the sol-gel process is preferably carried out by means of dip coating. To this end, in the simplest embodiment, the pre-structured substrate is dipped into a sol-filled cell by means of a lifting device and subsequently removed from the cell at a uniform speed.

The thickness of the applied layer depends on the depth and structure of the structuring carried out in the first process step. If a structuring is carried out with formation of many edges, corners and steps or large height differences between the highest and lowest points of the structure, the proportion of the smoothing layer should be selected correspondingly larger. Precise tuning of the individual parameters during structuring and subsequent smoothing is part of the expert knowledge of the person skilled in the art. The individual parameters are preferably matched to one another in such a way that the structured surface satisfies the conditions mentioned at the outset for an optimum diffuser/reflector. Control of the thickness during the coating in the sol-gel process depends in the case of dip coating essentially on the drawing speed of the structured substrate during coating. The greater the drawing speed, the thicker the layer obtained. The drawing speeds are usually in the range from 0.1 to 100 mm/sec and preferably in the range from 1.6 to 8 mm/sec. The coating operation can of course also be repeated one or more times until the desired smoothing of the structuring has been achieved.

For compression and solidification of the applied layer, the structured substrate can be calcined. The calcination removes the residual solvent fractions from the applied layer. The calcination temperatures are usually from 300 to 700° C., in particular from 500 to 600° C.

In a further embodiment of the present invention, the structured surface is additionally coated with a metal layer. This additional step follows the coating by the sol-gel process and can be carried out subsequently at any time. The coating with a metal layer can be carried out by wet-chemical methods, for example by suitable reduction processes, by the CVD process and/or PVD process, the PVD process being preferred.

Suitable as metal for the additional metal layer are, for example, aluminium, silver, chromium, nickel or other reflective metal layers. The metal layer is preferably aluminium.

The thickness of the additional metal layer depends on the material and the desired properties and is usually in the range from 10 to 150 nm and in particular in the range from 30 to 100 nm.

The present invention likewise relates to substrates having a structured surface, produced by one of the processes according to the invention.

The present invention furthermore relates to the use of substrates having a structured surface which are obtainable by the processes described above, as diffusers and/or reflectors in optical applications. The optical applications can be all optical applications known to the person skilled in the art, for example cameras of any design, projectors and projection screens, liquid-crystal displays, magnification systems, for example microscopes, etc. The substrates according to the invention are preferably used in liquid-crystal displays, where the structured substrates in accordance with the present invention can be employed particularly advantageously, for example as reflective background in order to replace backlighting and thus to enable a reduction in the energy consumption of the display. Further areas of application of the structured substrates in accordance with the present invention are evident to the person skilled in the art without inventive step.

The following examples are intended to explain the present invention in greater detail, but without limiting it.

### EXAMPLES

### Example 1

A glass plate having a thickness of 1 mm is blasted with glass beads having a size in the range from 10 to 50 μm at a jet pressure of 2 bar and from a separation of 200 mm. The plate is dedusted and dipped a total of three times into an aqueous/alcoholic SiO₂ sol (solids content: 3% by weight) at a drawing speed of 4 mm/sec. Between the individual dipping steps, the plate is in each case dried for 10 minutes at room temperature.

After the coating and drying, an aluminium layer having a layer thickness of 70 nm is applied to the structured and coated substrate.

A glass plate having a structured surface with diffuse-scattering properties is obtained.

1. Process for the structuring of surfaces of substrates, characterised in that a substrate is structured in a first step and, in a second step, coated by the sol-gel process for partial smoothing of the structuring.

2. Process according to claim 1, characterised in that a surface which scatters in a diffuse manner is obtained.

3. Process according to claim 1, characterised in that the structuring is carried out by the action of particle jets, laser beams, etching methods or embossing methods.

4. Process according to claim 3, characterised in that the particle jets are sand jets or electron beams.

5. Process according to claim 1, characterised in that the sols employed in the sol-gel process are sols of compounds of the elements titanium, zirconium, aluminium, silicon and/or mixtures thereof.

6. Process according to claim 1, characterised in that the coating in the sol-gel process is carried out by means of dip coating, spray methods or by means of a flow curtain.

7. Process according to claim 1, characterised in that the structured surface is additionally coated with a metal layer.

8. Process according to claim 7, characterised in that the coating with a metal layer is carried out by wet-chemical methods, by the CVD process and/or PVD process.

9. Process according to claim 7, characterised in that the metal is aluminium, silver, chromium, nickel or other reflective metal layers.

10. Substrates having a structured surface, produced by claim 1.

11. Substrates according to claim 10, characterised in that the substrate is a glass substrate, ceramic substrate, metal substrate or plastic substrate.

12. A method of diffusing or reflecting comprising employing substrates having a structured surface produced by one or more of processes of claim 1, as diffusers and/or reflectors in optical applications.

13. A method according to claim 12, characterised in that the optical applications are liquid-crystal displays.
